(19) United States
(12) Patent Application Publication
(10) Pub. No.: US 2021/0349159 A1
(43) Pub. Date: Nov. 11, 2021

(54) DIFFERENTIAL CURRENT MONITORING OF MULTIPLE CIRCUITS

(71) Applicant: Hamilton Sundstrand Corporation, Charlotte, NC (US)

(72) Inventor: John A. Dickey, Caledonia, IL (US)

(73) Assignee: Hamilton Sundstrand Corporation, Charlotte, NC (US)

(21) Appl. No.: 17/379,966

(22) Filed: Jul. 19, 2021

Related U.S. Application Data
(63) Continuation of application No. 15/392,766, filed on Dec. 28, 2016.

(51) Int. Cl. G01R 31/50; G06F 1/30; G06F 1/3206

(52) U.S. Cl. CPC G01R 31/50; G01R 19/0092; G06F 1/3206; G06F 1/305

(57) ABSTRACT

A system for differential current monitoring includes a control module and a plurality of nodes operatively connected to the control module. Each node is configured to monitor current from a bus to a respective load. The control module and nodes are configured to monitor current at each of the nodes, issue a pulse for each node, wherein the pulse has a duration that is proportional to current at the node, concatenate all of the pulses for the nodes to determine the total current drawn from the bus at the nodes, compare the total current drawn from the bus at the nodes to current input to the bus, and signal a fault condition if the total current drawn from the bus is not within a predetermined range of the current input to the bus.

### CROSS-REFERENCE TO RELATED APPLICATIONS

This application is a continuation of U.S. patent application Ser. No. 15/392,766, filed Dec. 28, 2016, the entire content of which is incorporated herein by reference.

### BACKGROUND OF THE INVENTION

### 1. Field of the Invention

The present disclosure relates to current protection, and more particularly to differential current monitoring for current protection.

### 2. Description of Related Art

When distributing power from a bus it is desirable to know when the power into the bus does not equal the sum of the power out of the bus through all the loads. This condition would indicate that there is current loss from the bus to an unwanted location such as ground, i.e., ground fault condition. To implement this check, the sum of all the loads has to be arithmetically subtracted from the source current. This has conventionally required measuring all the currents and then doing the arithmetic to calculate the sums and difference, which is hardware intensive.

Conventional differential current protection can be done by analog current summing or by complex digital arithmetic and high speed communications links. The digital method is often preferred due to the accuracy it provides, however it requires complex field programmable gate arrays (FPGAs) to generate the digital data and perform the sum and difference calculations fast enough to protect against a damaging fault condition.

The conventional techniques have been considered satisfactory for their intended purpose. However, there is an ever present need for improved differential current monitoring. This disclosure provides a solution for this problem.

### SUMMARY OF THE INVENTION

A system for differential current monitoring includes a control module and a plurality of nodes operatively connected to the control module. Each node is configured to monitor current from a bus to a respective load. The control module and nodes are configured to monitor current at each of the nodes, issue a pulse for each node, wherein the pulse has a duration that is proportional to current at (or through) the node, concatenate all of the pulses for the nodes to determine the total current drawn from the bus at the nodes, compare the total current drawn from the bus at the nodes to current input to the bus, and signal a fault condition if the total current drawn from the bus is not within a predetermined range of the current input to the bus.

The nodes can be arranged in a daisy chain and wherein issuing a pulse for each node includes sequentially issuing a pulse from one node to another along the daisy chain to create a pulse train, wherein each node in the daisy chain adds its pulse duration cumulatively to the total time to the end of the pulse train. The control module can be directly connected to a first one of the nodes and wherein issuing a pulse for each node includes issuing an initial pulse from a control module to the first one of the nodes to initiate transmission of the pulse train along the daisy chain. The control module can be directly connected to a final one of the nodes, wherein issuing a pulse for each node includes transmitting the pulse train back from a final one of the nodes in the daisy chain to the control module. The control module can be directly connected to each of the nodes, wherein the control module and nodes are configured to simultaneously issue a start pulse from a control module to each of the nodes so that all nodes sample their respective currents at the same time.

A method of differential current monitoring includes monitoring current at each of a plurality of nodes where loads are powered from a bus, issuing a pulse for each node, wherein the pulse has a duration that is proportional to current at the node, concatenating all of the pulses for the nodes to determine the total current drawn from the bus at the nodes, comparing the total current drawn from the bus at the nodes to current input to the bus, and signaling a fault condition if the total current drawn from the bus is not within a predetermined range of the current input to the bus.

Summing all of the pulses can include measuring duration of round trip time from the first pulse out of the control module until the end of the very last pulse back to the control module, wherein the duration of round trip time is proportional to the sum of all the current through the nodes. The method can include monitoring for a timeout condition in the control module in response to failure to receive the pulse train from the last one of the nodes in the daisy chain, and reporting a fault in response to the timeout condition. Each of the nodes can use a common time/current scale factor for issuing the respective pulse, so the number of nodes can be adjusted.

These and other features of the systems and methods of the subject disclosure will become more readily apparent to those skilled in the art from the following detailed description of the preferred embodiments taken in conjunction with the drawings.

### BRIEF DESCRIPTION OF THE DRAWINGS

So that those skilled in the art to which the subject disclosure appertains will readily understand how to make and use the devices and methods of the subject disclosure without undue experimentation, preferred embodiments thereof will be described in detail herein below with reference to certain figures, wherein:

FIG. 1 is a schematic view of an exemplary embodiment of a system constructed in accordance with the present disclosure, showing the daisy chain arrangement of nodes monitoring current from a bus to respective loads; and

FIG. 2 is a timing diagram of the system of FIG. 1, showing the pulse train for an exemplary embodiment with four nodes.

### DETAILED DESCRIPTION OF THE PREFERRED EMBODIMENTS

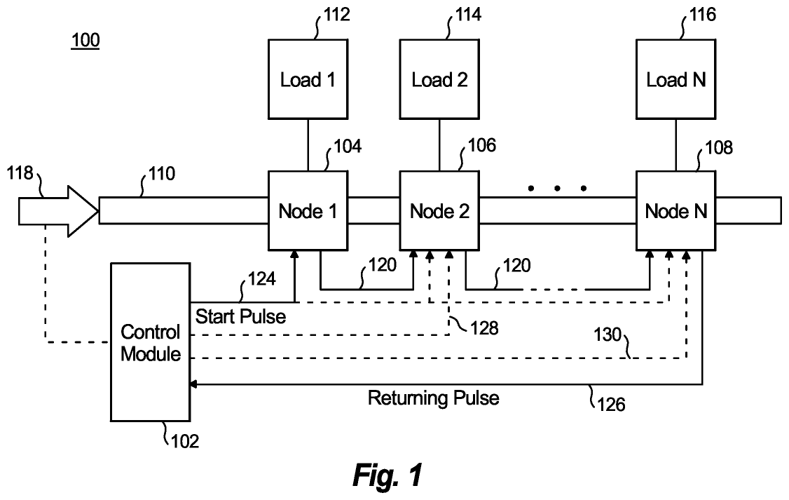

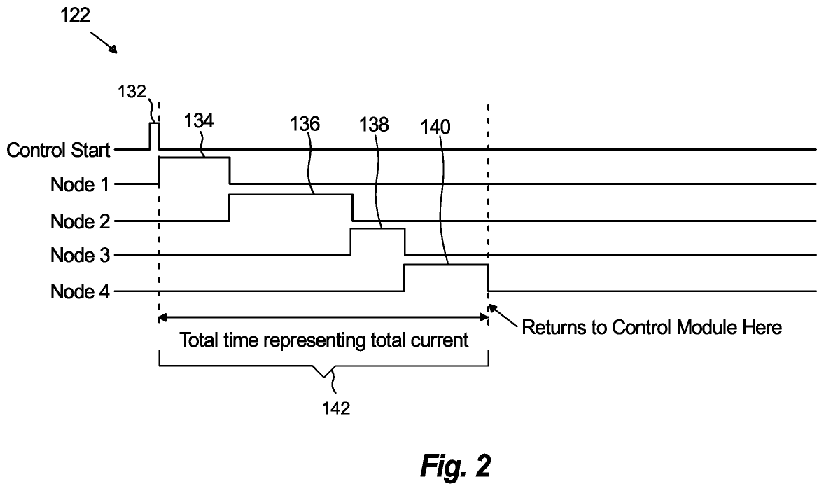

Reference will now be made to the drawings wherein like reference numerals identify similar structural features or aspects of the subject disclosure. For purposes of explanation and illustration, and not limitation, a partial view of an exemplary embodiment of a system in accordance with the disclosure is shown in FIG. 1 and is designated generally by reference character 100. Other embodiments of systems in accordance with the disclosure, or aspects thereof, are provided in FIG. 2, as will be described. The systems and methods described herein can be used for differential current monitoring, for example in high power and/or solid state systems.

System 100 for differential current monitoring includes a control module 102 and a plurality of nodes 104, 106, and 108 operatively connected to the control module 102. Each node 104, 106, and 108 is configured to monitor current from a bus 110 to a respective load 112, 114, and 116. Those skilled in the art will readily appreciate that while shown and described in the exemplary context of having three nodes 104, 106, and 108, the ellipsis in FIG. 1 indicate any suitable number of nodes and respective loads can be included without departing from the scope of this disclosure.

The control module 102 and nodes 104, 106, and 108 are configured to monitor current at each of the nodes 104, 106, and 108 and issue a pulse for each node 104, 106, and 108 (the control module 102 need only directly monitor the current at input 118 of bus 110 and need have no direct bearing on the measurement of current at the nodes 104, 106, and 108). The pulse from each node has a pulse duration that is proportional to current measured or monitored at the node 104, 106, and 108. Control module 102 can sum all of the pulses, e.g. pulse durations, for the nodes 104, 106, and 108 to determine the total current drawn from the bus 110 at the nodes 104, 106, and 108. The concatenation of the pulses is what performs the sum. The control module can simply measure the resulting pulse duration from end to end and compares to the current 118. In other words the summation can be the inherent result of the daisy chain of the pulses as further explained below.

Control module 102 is connected to the input 118 of bus 110 so control module 102 can compare the total current drawn from the bus 110 at the nodes 104, 106, and 108 to the current input to the bus 110. If the total current drawn from the bus 110 is not within a predetermined range of the current input to the bus 110, control module 102 can signal a fault condition, such as a ground mode fault.

The nodes 104, 106, and 108 are arranged in a daisy chain 120. Issuing a pulse for each node 104, 106, and 108 can include sequentially issuing a pulse from one node to another along the daisy chain 120 to create a pulse train 122 shown in FIG. 2 and described below, wherein each node 104, 106, and 108 in the daisy chain 120 adds its pulse duration cumulatively to the total time to the end of the pulse train 122. Summing all of the pulses can include measuring duration of round trip time from the first pulse out of the control module 102 until the end of the very last pulse back to the control module 102 from node 108. The duration of round trip time is proportional to the sum of all the current through the nodes 104, 106, and 108.

The control module 102 is directly connected to a first one of the nodes 104 at line 124. Issuing a pulse for each node 104, 106, and 108 can include issuing an initial pulse from control module 102 to the first one of the nodes 104 to initiate transmission of the pulse train 122 along the daisy chain 120. The control module 102 is directly connected to a final one of the nodes 108 at line 126, wherein issuing a pulse for each node 104, 106, and 108 includes transmitting the pulse train 122 back from the final one of the nodes 108 in the daisy chain 120 to the control module 102.

The control module 102 can optionally be directly connected to each of the nodes 104, 106, and 108, e.g., using the dashed extensions of line lines 124 in FIG. 1, or using dedicated lines 128 and 130. In this arrangement, the control module 102 and nodes 104, 106, and 108 can be configured to simultaneously issue a start pulse from the control module 102 to each of the nodes 104, 106, and 108 so that all nodes 104, 106, and 108 sample their respective currents at the same time. The nodes 106 and 108 delay issuing their pulses until the node 104 transmits is pulse to node 106, which transmits its pulse and so on along the daisy chain 120 as described above until the pulse train 122 is returned to control module 102. This arrangement with simultaneous current sampling from all nodes 104, 106, and 108 can be used to reduce errors arising from changes in load while sampling. Both methods, e.g., sending a start pulse to each node simultaneously versus sending a start pulse from each node to the next, can be used and the resulting total sum of current drawn from bus 110 can be compared across the two methods as in internal test for fault modes, e.g., wherein a fault is detected if the difference in pulse train duration across these two methods fails to fall within a predetermined limit.

The method can include monitoring for a timeout condition in the control module 102 in response to failure to receive the pulse train 122 from the last one of the nodes 108 in the daisy chain 120, and reporting a fault in response to the timeout condition. Each of the nodes 104, 106, and 108 can use a common time/current scale factor for issuing the respective pulse, regardless of the number of nodes. The number of nodes can be adjusted, e.g., if loads are added or removed from bus 110.

FIG. 2 shows a start pulse 132, which is issued along line 124 to node 104. Node 104 issues its pulse 134 to node 106 along daisy chain 120. The length or duration of pulse 134 along the horizontal axis in FIG. 2 is proportional to the current monitored at node 104. Node 106 likewise issues its pulse to the next node (in FIG. 2 an exemplary four nodes are used), which issues its pulse 138 to final node 108, which issues its pulse 140 back to control module 102. The total time 142 measured at control module 102 from the end of the start pulse 132 to the end of the pulse train 122, in other words, the end of pulse 140 from the final node 108, is proportional to the sum of the current drawn from bus 110. Those skilled in the art will readily appreciate, having the benefit of this disclosure, that while shown and described in the exemplary context of current monitoring, any suitable metric can be monitored without departing from the scope of this disclosure.

As will be appreciated by one skilled in the art, aspects of the present embodiments may be embodied as a system, method or computer program product. Accordingly, aspects of the present embodiments may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described above with reference to flowchart illustrations and/or block diagrams of methods, apparatus (systems) and computer program products according to embodiments of the embodiments. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in a flowchart and/or block diagram block or blocks.

Embodiments described herein provide a hybrid digital/analog system and method for differential monitoring of multiple circuits. The methods and systems of the present disclosure, as described above and shown in the drawings, provide for differential current monitoring with superior properties including better noise immunity and accuracy than conventional analog systems and reduced hardware relative to conventional digital techniques. Potential benefits of embodiments disclosed herein include the ability to obtain digital accuracy without the need for field programmable gate arrays (FPGAs) and digital signal processing arithmetic functions, and making use of simple pulse width modulation (PWM) logic that is built into embedded controllers for generating time/current pulses and using a simple timer/counter or simple subtraction to determine if input and output currents are equal. While the apparatus and methods of the subject disclosure have been shown and described with reference to preferred embodiments, those skilled in the art will readily appreciate that changes and/or modifications may be made thereto without departing from the scope of the subject disclosure.

What is claimed is:

1. A system comprising:
a control module having pulse-width-modulation logic; and
a plurality of nodes operatively connected to the control module, wherein each node is configured to:
monitor itself for a metric;
receive a pulse from a sequentially previous node in the plurality of nodes, except in the case of a first one of the nodes which does not have a sequentially previous one of the nodes; and
issue a pulse having a duration equal to a sum of a duration of the pulse received from the sequentially previous node, if there is a sequentially previous node, plus a component that is proportional to the metric monitored at the node,
wherein a sequentially final one of the nodes issues a pulse that is a concatenation of the pulses of all the nodes,
wherein the control module is directly connected to each of the nodes such that control module is configured to simultaneously issue a first monitor pulse from the control module to each of the nodes to begin monitoring for the metric at the same time.

2. The system as recited in claim 1, wherein the control module and nodes are configured to:
compare total current drawn from a bus at the nodes to current input to the bus; and
signal a fault condition if the total current drawn from the bus is not within a predetermined range of the current input to the bus.

3. The system as recited in claim 1, wherein the nodes are arranged in a daisy chain and wherein issuing a pulse for each node includes sequentially issuing a pulse from one node to another along the daisy chain to create a pulse train, wherein each node in the daisy chain adds its pulse duration cumulatively to the total time to the end of the pulse train.

4. The system as recited in claim 3, wherein the control module is directly connected to a first one of the nodes and wherein issuing a pulse for each node includes issuing a second initiation pulse from the control module to the first one of the nodes to initiate transmission of the pulse train along the daisy chain.

5. The system as recited in claim 3, wherein the control module is directly connected to a final one of the nodes, and wherein issuing a pulse for each node includes transmitting the pulse train back from the final one of the nodes in the daisy chain to the control module.

6. A method of monitoring comprising:
monitoring a metric at each of a plurality of nodes;
issuing a pulse for each node, wherein the pulse has a duration that is proportional to the metric monitored at the node; and
concatenating a duration of all of the pulses for the nodes.

7. The method as recited in claim 6, further comprising:
comparing total current drawn from a bus at the nodes to current input to the bus; and
signaling a fault condition if the total current drawn from the bus is not within a predetermined range of the current input to the bus.

8. The method as recited in claim 6, wherein the nodes are arranged in a daisy chain and wherein issuing a pulse for each node includes sequentially issuing a pulse from one node to another along the daisy chain to create a pulse train, wherein each node in the daisy chain adds its pulse duration cumulatively to the total time to the end of the pulse train.

9. The method as recited in claim 8, wherein issuing a pulse for each node includes issuing an initial pulse from a control module to a first one of the nodes to initiate transmission of the pulse train along the daisy chain.

10. The method as recited in claim 8, wherein issuing a pulse for each node includes transmitting the pulse train back from a final one of the nodes in the daisy chain to a control module.

11. The method as recited in claim 8, wherein issuing a pulse for each node includes issuing an initial pulse from a control module to a first one of the nodes initiate transmission of the pulse train along the daisy chain, wherein issuing a pulse for each node includes transmitting the pulse train back from a final one of the nodes in the daisy chain to the control module, further comprising concatenating all of the pulses including measuring duration of round trip time from the first pulse out of the control module until the end of the very last pulse back to the control module, wherein the duration of round trip time is proportional to the sum of all the current through the nodes.

12. The method as recited in claim 8, further comprising monitoring for a timeout condition in the control module in response to failure to receive the pulse train from the last one of the nodes in the daisy chain; and reporting a fault in response to the timeout condition.

13. The method as recited in claim 6, wherein each of the nodes uses a common time/current scale factor for issuing the respective pulse.

14. The method as recited in claim 6, further comprising adjusting the number of nodes.

15. The method as recited in claim 6, further comprising simultaneously issuing a start pulse from a control module to each of the nodes so that all nodes sample their respective currents at the same time.

16. The method as recited in claim 17, wherein the nodes are arranged in a daisy chain and wherein issuing a pulse for each node includes sequentially issuing a pulse from one node to another along the daisy chain to create a pulse train, wherein each node in the daisy chain adds its pulse duration cumulatively to the total time to the end of the pulse train.
